(19) United States
(12) Patent Application Publication
(10) Pub. No.: US 2007/0281183 A1
(43) Pub. Date: Dec. 6, 2007

(54) Film formation method, die, and method of manufacturing the same

(75) Inventors: Shigeru Hosoe, Hachioji-shi (JP); Hiroyuki Matsuda, Sagamihara-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KONICA MINOLTA OPTO INC.

(21) Appl. No.: 11/802,851

(22) Filed: May 25, 2007

(30) Foreign Application Priority Data
May 31, 2006 (JP) JP2006-152187

(51) Int. Cl. C23C 16/00; B32B 9/00

(52) U.S. Cl. 428/698; 427/249.1

(57) ABSTRACT

An objective is to provide a film formation method with which a layer having reduced defects, a die obtained by the film formation method, and a method of manufacturing the die. Free carbons increase in the case of reducing hydrogen gas as a carrier gas, so that concave portions are generated and increased during the molding transfer surface process. It was commonly known that hydrogen gas employed for the thermal CVD was set to 2 moles, but it was found out that generation of concave portions was possible to be largely inhibited by setting hydrogen gas to at least 3 moles. However, a level of up to 8 moles is preferable in view of practical use, since dilution of the total raw material gas causes a decline of reaction speed in the case of too much increase of hydrogen gas, resulting in the low speed of film formation.

This application claims priority from Japanese Patent Application No. 2006-152187 filed on May 31, 2006, which is incorporated hereinto by reference.

### FIELD

The present invention relates to a film formation method with which a layer having reduced defects, a die obtained by the film formation method, and a method of manufacturing the die.

### BACKGROUND

Ceramic materials have an advantage over other materials in view of heat resistance, weight and dimensional stability, when being employed for an optical element and a die to form the element. When the ceramic materials are directly employed for an optical element molding die, for example, a very light weight die can be obtained, resulting in contributing to lightweight and downsizing of a supporting member, since they have 5 times lower specific gravity, compared with superhard materials. Further, there is a problem such that an optical surface is gradually fogged in the case of an atmosphere temperature exceeding 500° C., since oxidation resistance of tungsten carbide is not so high when using the tungsten carbide as a superhard material. However, in the case of ceramic materials such as oxide, nitride and carbide, no optical surface is fogged up to approximately 1000° C., resulting in excellent heat resistance. Further, as to the dimensional stability, shape in the case of the ceramic materials can be stabilized with respect to temperature change, compared with that in the case of iron and a stainless material, since ceramic materials have a linear expansion coefficient of 1×10⁻⁶-7×10⁻⁶.

A technique of forming a film of β-SiC via thermal CVD is disclosed in Patent Document 1.

(Patent Document 1) Japanese Patent O.P.I. Publication No. 11-79760.

### SUMMARY

Ceramic materials exhibit excellent properties as a material to form a molding transfer surface for transferring an optical surface of an optical element, but there appears some serious problems. One of them is originated from a preparation method, and fine holes tend to be generated in a sintered texture structure, since a die base material is commonly formed by sintering via heat application of the ceramic material powder. Therefore, there is a problem such that a surface roughness was not improved, even though finishing the molding transfer surface via machining processes such as grinding and polishing. On the other hand, in the case of a metal material and a superhard material, they can be more easily handled than ceramic materials, since a material with the reduced number of holes is comparatively easy to be acquired by employing a higher purity of the composition or changing a sintering agent.

There is another problem such that cutting chips and cracks are easily generated during a machining process to form a molding transfer surface, since ceramic materials are hard and brittle, whereby it is difficult to form the molding transfer surface with accuracy because of fine cracks generated on the processing surface. Further, care should be taken when handling an optical element and a molding die, and there is also a problem such that cutting chips and cracks are easily generated by applying an excess force locally or an impact force.

As a method to solve problems based on the foregoing ceramic material texture structure, a thermal CVD (chemical vapor deposition) method is utilized. This method is a method of forming a ceramic material while undergoing chemical reaction by bringing raw material gas into contact with a substrate at high temperature, and a ceramic material having a very dense texture structure with no hole can be formed on the substrate surface. Incidentally, the ceramic material is no only used as a layer formed on the substrate surface, but also is used as a bulk material by producing a thicker film.

Silicon carbide, titanium carbide, tantalum carbide and so forth are provided as ceramic materials obtained via the thermal CVD, but when silicon carbide commonly used as an optical element material or an optical element molding die material is taken as an example, silicon tetrachloride (SiCl₄), methane (CH₄) or such is employed as a raw material gas, and hydrogen (H₂) is employed as a carrier gas. These gases are mixed in a predetermined mole ratio (refer to Formula (1), for example) in advance, are introduced into an atmosphere heated to 1100-1400° C., and are brought into contact with a substrate in the foregoing atmosphere, so that reaction takes place, and silicon carbide (SiC) adheres to the surface to form a film having an even texture structure. In the case of titanium carbide, tantalum carbide and so forth, the basically similar reaction takes place, though a different kind of gas is employed.

SiCl₄+2H₂+CH₄→SiC+4HCL+2H₂ (1)

It is preferable that a substrate material is the same as a film forming material in order to prevent stress generation during cooling, since the thermal CVD is conducted at high temperature. Accordingly, it is known that a ceramic material formed by sintering is utilized for a substrate, and the film formation of the same kind of ceramic material is made thereon via a thermal CVD treatment.

As to the dense ceramic material obtained in this way, the molding transfer surface which is formed once becomes very smooth, and the surface having no hole can be obtained. Furthermore, the ceramic material exhibits preferable properties such as no surface fogged at high temperature, scratch resistance because of being hard, and not much of generation of shape change by temperature change. Therefore, the ceramic material obtained via thermal CVD is utilized as a die material to mold a very high precision optical element and a glass optical element.

On the other hand, in view of easy generation of cutting chips and cracks as a problem, similarly to the case of the ceramic material employed for forming a film via thermal CVD, sufficient solution has not been found out through this ceramic material film formation. However, there appears a profound problem such as fine cutting chips and cracks produced during a process of forming a molding transfer surface in the case of the ceramic material obtained via thermal CVD, since the higher quality molding transfer surface is demanded than that of a ceramic material formed via sintering. Next, the foregoing problem will be described referring to an example in which silicon carbide formed via a conventional thermal CVD has been mirror-finished.

A silicon carbide film was formed on a sintered silicon carbide substrate via a conventional thermal CVD by the inventors, and the surface was smoothed by grinding to conduct a ductile mode cutting process. In the case of a silicon carbide film obtained via the conventional thermal CVD, a lot of fine concave portions (referred to as holes that seem to be generated by digging the surface) having a size of 1-2 μm or more on the surface obtained after the ductile mode cutting process can be seen in FIG. 12. It is assumed that when a local force is applied to the ceramic surface on which a blade edge of a diamond tool is formed via the thermal CVD, stress is concentrated since both sides are very hard, and hardly elastically deformed, so that a weak portion in the ceramic structure is broken and cutting chips fall off. It is also assumed that large wear at the blade edge of the diamond tool is observed in the ductile mode cutting process in which a lot of fine concave portions are produced, whereby defects such as chipping are generated at the tool blade edge during generation of ceramic concave portions. Thus, life of the tool is largely shortened, but the number of concave portions further increase when the ductile mode cutting process is continuously conducted in wear form. The details are sketchy, but not only the surface roughness is lowered, but also no molding transfer surface in high precision shape accuracy can be formed since it is assumed that in the following vicious spiral, a blade edge with no sharpness caused by wear is cut in, whereby, a larger stress is generated onto the ceramic surface, resulting in generation of concave portions and increasing of blade edge wear.

Similar concave portions can also be seen when an optical mirror surface is to be obtained via grinding. There is a clear tendency such that a lot of large concave portions are generated in the case of a large size of abrasive grains, and a reduced amount of small concave portions is generated in the case of a small size of abrasive grains. Further, in the case of an elastically deformable material such as a resin usable as a binder even though the grind stone has the same abrasive grains in size, concave portions are comparatively reduced, and in the case of a hard material such as a vitrified grinding wheel, a lot of concave portions tend to be generated. Incidentally, the details of formation of a molding transfer surface via a ductile mode cutting process of a higher hardness material are described by the inventors in Japanese Patent O.P.I. Publication No. 2004-223700.

Concave portions at this level were not recognized since a die for molding a conventional optical element was within the allowable range with respect to desired performance of the optical element, but they have been demanded in recent years. As for application of a high precision optical element and an optical element with a short wavelength of use, there appear disclosed problems such that light flux scattering is generated, imaging contrast is lowered, and light amount loss of transmitted light and reflected light results, since corresponding protrusions are generated on the optical surface of an optical element molded by a die with a molding transfer surface having concave portions.

In the case of an imaging lens for a digital camera, for example, the number of pixels increases despite the fact that the lens diameter becomes smaller, and demanding for defects on the lens surface becomes relatively severe, depending on desired performance. Further, in the case of an optical element for an optical disk employing a blue semiconductor laser which has put into practical use in recent years, the wavelength of the blue semiconductor laser is ⅔ times shorter than that of a red semiconductor laser, and the scattered light amount increases by 5 times, whereby the light amount of use has largely been lowered, since Rayleigh scattering generated by protrusions on an optical surface caused by concave portions is inversely proportional to the fourth power of the wavelength. Accordingly, it is to be gradually understood that a silicon carbide film obtained via a conventional thermal CVD tends possibly to produce a practical problem, since defects such as concave portions on a molding transfer surface of a die to form an optical element in this application, which have been seen as no problem, should be inhibited as much as possible.

The present invention was made on the basis of the above-described problematic situation of the conventional technique. It is an object of the present invention to provide a film formation method with which a layer having reduced defects, a die obtained by the film formation method, and a method of manufacturing the die. Also disclosed is a film formation method comprising the step of forming a film of a carbide via a thermal CVD employing a hydrogen, and a chloride or a hydrocarbon used as a raw material gas, wherein a gas flow rate of the hydrogen is 3-8 times larger than a gas flow rate of the chloride or the hydrocarbon.

### BRIEF DESCRIPTION OF THE DRAWINGS

Embodiments will now be described, by way of example only, with reference to the accompanying drawings which are meant to be exemplary, not limiting, and wherein like elements numbered alike in several figures, in which:

FIG. 1 is a schematic cross-sectional diagram showing a thermal CVD treatment apparatus,

FIG. 2 is a cross-sectional view showing a die material treated via the thermal CVD,

FIG. 3 is an SEM micrograph (a magnification of 50 times) of the film surface formed via the thermal CVD when 1 mole of hydrogen gas is arranged with respect to 1 mole of each raw material gas,

FIG. 4 is an SEM micrograph (a magnification of 50 times) of the film surface formed via the thermal CVD when 2 moles of hydrogen gas are arranged with respect to 1 mole of each raw material gas,

FIG. 5 is an SEM micrograph (a magnification of 50 times) of the film surface formed via the thermal CVD when 3 moles of hydrogen gas are arranged with respect to 1 mole of each raw material gas,

FIG. 6 is a differential interference microscope micrograph (a magnification of 200 times) of the surface formed by cutting in ductile mode a film formation surface obtained via the thermal CVD when 1 mole of hydrogen gas is arranged with respect to 1 mole of each raw material gas,

FIG. 7 is a differential interference microscope micrograph (a magnification of 200 times) of the surface formed by cutting in ductile mode a film formation surface obtained via the thermal CVD when 2 moles of hydrogen gas are arranged with respect to 1 mole of each raw material gas,

FIG. 8 is a differential interference microscope micrograph (a magnification of 200 times) of the surface formed by cutting in ductile mode a film formation surface obtained via the thermal CVD when 3 moles of hydrogen gas are arranged with respect to 1 mole of each raw material gas,

FIG. 9 is an SEM micrograph (a magnification of 5000 times) of the film surface formed via the thermal CVD when 1 mole of hydrogen gas is arranged with respect to 1 mole of each raw material gas,

FIG. 10 is an SEM micrograph (a magnification of 5000 times) of the film surface formed via the thermal CVD when 2 moles of hydrogen gas are arranged with respect to 1 mole of each raw material gas,

FIG. 11 is an SEM micrograph (a magnification of 5000 times) of the film surface formed via the thermal CVD when 3 moles of hydrogen gas are arranged with respect to 1 mole of each raw material gas,

FIG. 12 is an SEM micrograph (a magnification of 1000 times) of the surface formed by cutting in ductile mode a film formation surface obtained via the thermal CVD when 1 mole of hydrogen gas is arranged with respect to 1 mole of each raw material gas,

FIG. 13 is an SEM micrograph (a magnification of 1000 times) of the surface formed by cutting in ductile mode a film formation surface obtained via the thermal CVD when 2 moles of hydrogen gas are arranged with respect to 1 mole of each raw material gas,

FIG. 14 is an SEM micrograph (a magnification of 1000 times) of the surface formed by cutting in ductile mode a film formation surface obtained via the thermal CVD when 3 moles of hydrogen gas are arranged with respect to 1 mole of each raw material gas,

FIG. 15 is a stereomicroscope of an optical surface molding-transferred from molding transfer surface 10a after molding a glass lens employing die 10; and

FIG. 16 is a resulting figure obtained by observing performance of the optical surface shown in FIG. 15 at the interference wavefront of a blue semiconductor laser.

### DESCRIPTION OF THE PREFERRED EMBODIMENTS

(Structure 1) A film formation method comprising the step of forming a film of a carbide via a thermal CVD employing a hydrogen, and a chloride or a hydrocarbon used as a raw material gas, wherein a gas flow rate of the hydrogen is 3-8 times larger than a gas flow rate of the chloride or the hydrocarbon.

After considerable effort during intensive studies, the inventors have found out that a carbide film having a dense texture structure, in which defects such as holes are reduced, is successfully formed via the thermal CVD. By applying this to a die to mold an optical element and so forth, a die hardly generating cutting chips and cracks can be obtained during a cutting process of the molding transfer surface. Incidentally, the above-described gas flow rate (amount of gas flow per unit time) of the hydrogen is preferably 3-6 times larger than a gas flow rate of the chloride or the hydrocarbon used as a raw material gas, and more preferably 3-5 times larger than a gas flow rate of the chloride or the hydrocarbon used as a raw material gas.

Next, the present invention will be described in detail.

The basic chemical reaction of a thermal CVD treatment is shown in Formula (1) employing silicon carbide as an example, but the significant point herein is that silicon tetrachloride is directly reduced with hydrogen gas rather than methane gas to obtain silicon. Specifically, as shown in Formula (2), two moles for a mole ratio of hydrogen gas with respect to one mole of each raw material gas remain unchanged before and after the reaction, but hydrogen gas called a carrier gas is also employed to surely reduce silicon.

SiCl₄+2H₂+CH₄→Si+4HCL+CH₄→SiC+4HCL+2H₂ (2)

Silicon carbide having 50 mol % of silicon and 50 mol % of carbon in composition formed via the thermal CVD is brownish yellow, and transparent in the case of the thin film. The silicon carbide becomes black-opaque by increasing only a few percent of carbon content. Each silicon carbide formed via the thermal CVD is completely black-opaque, and there is a slightly larger amount of carbon content than that of silicon in composition. In other words, it is understood that silicon content is slightly insufficient in composition.

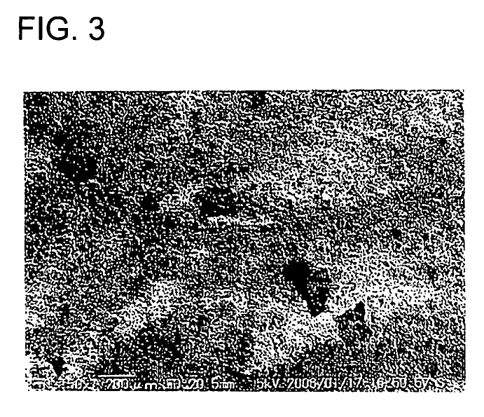

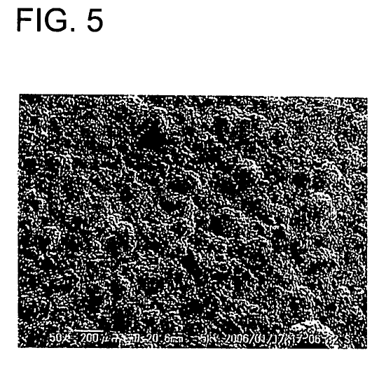

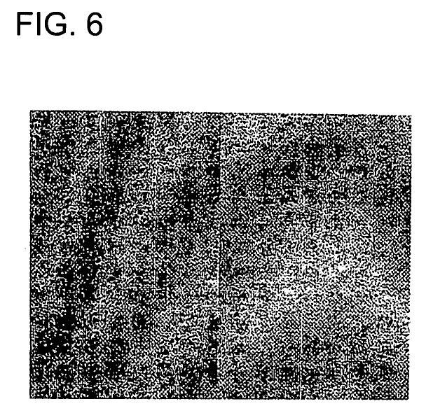

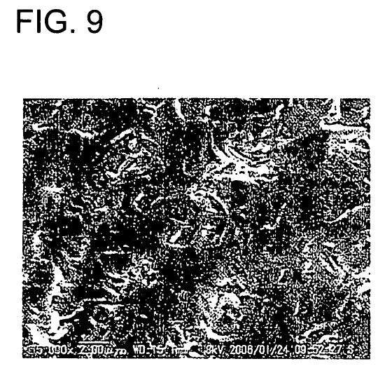

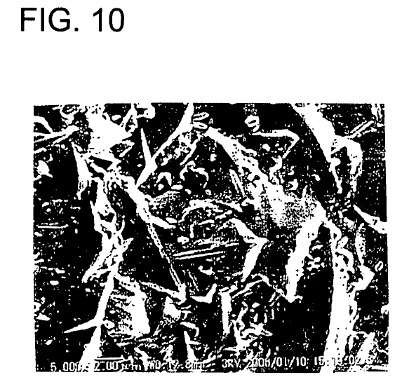

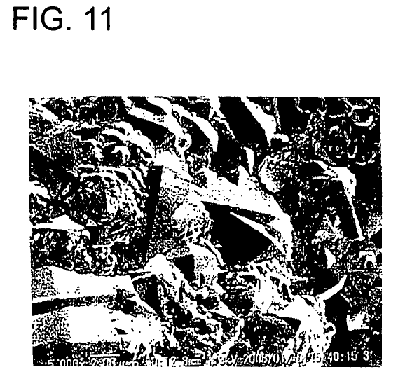

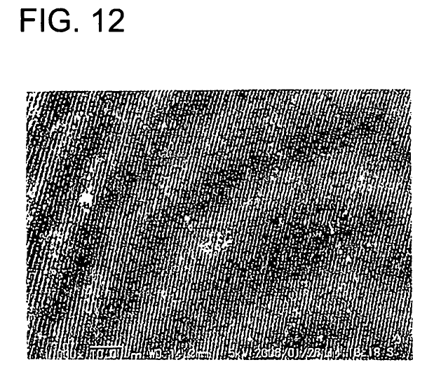

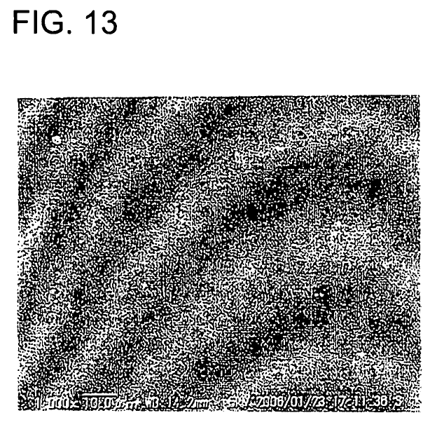

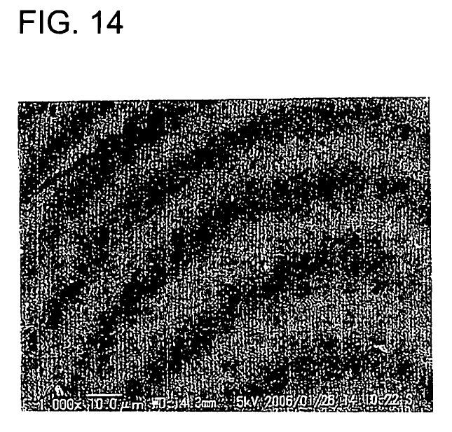

Focusing on hydrogen gas as a carrier gas, the inventors conducted film formation of silicon carbide via the thermal CVD by varying the composition. The film formation was conducted under three conditions such as 1 mole of hydrogen gas, 2 moles (conventional) and 3 moles (that is, 1, 2 and 3 times in gas flow rate) with respect to 1 mole of each raw material gas, without changing gas flow rate of the raw material gas (silicone tetrachloride gas and methane gas). SEM micrographs (a magnification of 50 times) of the film surface formed under the conditions via the thermal CVD are shown in FIGS. 3, 4 and 5, and differential interference microscope micrographs (a magnification of 200 times) of the surface formed by cutting a molding transfer surface in ductile mode are shown in FIGS. 6, 7 and 8. For comparison, SEM micrographs (a magnification of 5000 times) of the film surface formed as the conventional example are shown in FIGS. 9, 10 and 11, and SEM micrographs (a magnification of 1000 times) of the surface obtained after a cutting process as the conventional example are shown in FIGS. 12, 13 and 14,

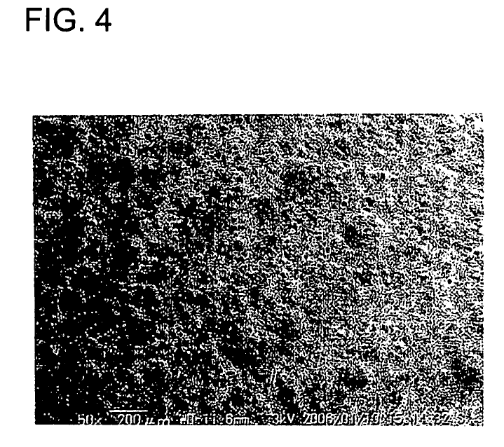

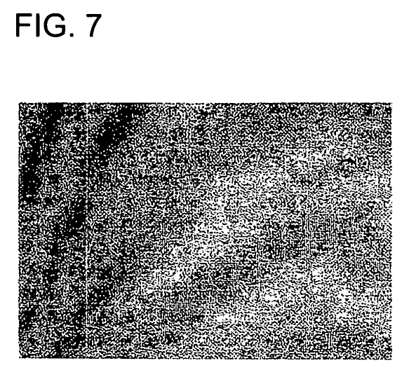

When hydrogen gas is reduced to 1 mole, a fine roughened structure on the surface, as shown in FIG. 3, is observed so as to have seemingly formed a dense layer. However, upon making a component analysis of the surface, since black spots were seen in places, it was found out that there were some local portions having a carbon content of at least 80%, and free carbons are contained in these portions. It was also found out that concave portions on the surface after processing the molding transfer surface as shown in FIG. 6 were generated far more than in the conventional condition, and it was unsatisfactory in this case to employ the condition for the thermal CVD. Further, in the case of hydrogen gas being set to 2 moles, the number of concave portions are reduced, but a certain number of concave portions remains (refer to FIGS. 4 and 7).

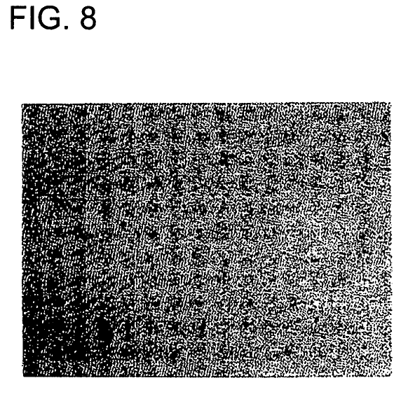

On the other hand, in the case of hydrogen gas being set to 3 moles, generation of concave portions after processing the molding transfer surface was largely reduced as shown in FIG. 8, despite the fact that the total gas flow was increased. The number of concave portions were counted in FIGS. 3-5. In the case of 1 mole of hydrogen gas, counted was at least 1000 in a visible field of 0.135 mm² (430 μm×315 μm), 257 in the case of 2 mole of hydrogen gas (conventional), and 14 in the case of 3 mole of hydrogen gas. In unit area conversion, at least 7400/mm², 1903/mm²104/mm², respectively. The conventional condition in the case of 2 moles of hydrogen gas is not appropriate for the molding transfer surface to produce transfer formation of the foregoing high precision optical surface, but the condition in the case of 3 moles of hydrogen gas is optically appropriate. Accordingly, the number of concave portions of at most 1000/mm² is preferable, but the number of concave portions of at most 300/mm² is more preferable specifically in the case of severe demanding application, whereby an optical element having a high precision optical surface can be obtained.

The inventors have found out from the above-described results that free carbons increase in the case of reducing hydrogen gas as a carrier gas, so that concave portions are generated and increased during the molding transfer surface process. As disclosed in Patent Document 1, it was commonly known that hydrogen gas employed for the thermal CVD was set to 2 moles, but it was found out for the first time from the studies done by inventors that generation of concave portions was possible to be largely inhibited by setting hydrogen gas to at least 3 moles. However, a level of up to 8 moles is preferable in view of practical use, since dilution of the total raw material gas causes a decline of reaction speed in the case of too much increase of hydrogen gas, resulting in the low speed of film formation.

(Structure 2) The film formation method of Structure 1, wherein the carbide is silicon carbide. Since silicon carbide exhibits high heat resistance together with high hardness, it is preferable as a die material of an optical element formed from glass as a material. Titanium carbide, tantalum carbide and so forth are also usable as the die material.

(Structure 3) A die formed by the film formation method of Structure 1 or 2, wherein when cutting a surface of a substrate on which the film of the carbide is formed to form a molding transfer surface, the number of cutting chips per unit area of the cut surface is at most 1000/mm². Thus, an optical element having a high precision optical surface can be molded. Herein, the number of cutting chips means the number of concave portions having a maximum span size of at least 1 μm.

(Structure 4) A method of manufacturing a die, comprising the steps of forming a film of a carbide on a surface of a substrate via a thermal CVD, with controlling that a hydrogen gas flow rate is 3-8 times larger than a gas flow rate of a chloride or a hydrocarbon used as a raw material gas; and forming a molding transfer surface by ductile-mode-cutting the surface of the substrate on which the film of the carbide is formed employing a diamond tool.

As described above, when ductile-mode-cutting the foregoing substrate surface on which a film of carbide is formed employing a diamond tool, reduced concave portions result in the higher precision mirror surface. That is, according to the present invention, a hydrogen gas flow rate is 3-8 times larger than a gas flow rate of a chloride or a hydrocarbon used as a raw material, and a film of a carbide is formed on the substrate surface via the thermal CVD to inhibit generation of concave portions, whereby a die having a high precision molding transfer surface can be produced.

(Structure 5) The method of Structure 4, further comprising the step of molding-transferring from the molding transfer surface to an optical surface of an optical element, wherein the die is employed to mold the optical element.

(Structure 6) The method of Structure 4 or 5, wherein the carbide is silicon carbide.

(Structure 7) The method of any one of Structures 4-6, further comprising the step of forming a release film on the molding transfer surface. Thus, the optical element can easily be released from the die after molding.

While the preferred embodiments of the present invention have been described using specific terms, such description is for illustrative purposes only, and it is to be understood that changes and variations may be made without departing from the spirit or scope of the appended claims.

### DETAILED DESCRIPTION OF THE INVENTION

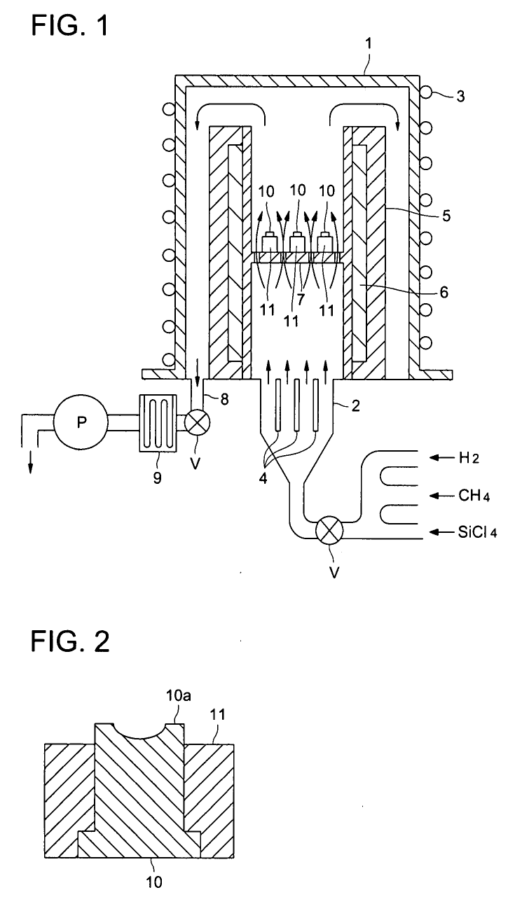

Next, embodiments of the present invention will be described referring to figures. FIG. 1 is a schematic cross-sectional diagram showing a thermal CVD treatment apparatus. FIG. 2 is a cross-sectional view showing a die material treated via the thermal CVD.

In FIG. 1, gas supply passage 2 is provided at the bottom of chamber 1 to shield the inside against the external environment. Gas supply passage 2 is connected to a gas supply source (no figure shown) via valve V. Silicon tetrachloride gas, methane gas and hydrogen gas are arranged to be supplied from the gas supply source, and these are mixed and supplied to the inside of chamber 1 via rectification of these gases employing current plate 4 placed at the end of gas supply passage 2.

Cylindrical adiabatic supporting member 5 is placed in the center of chamber 1. Cylindrical carbon heater 6 is placed in the inner circumference of cylindrical adiabatic supporting member 5, and base 7 on which die material 10 is placed is further situated medially thereto. A lot of holes are formed in the portions of base 7 on which die material 10 is placed, and it is designed that the mixed gas flows upward from the bottom of chamber 1 with no interruption.

The mixed gas which passes through die material 10 flows around outward from the upper portion of supporting member 5, and passes through between supporting member 5 and the inner wall to flow into exhaust passage 8. Passage 8 is connected to exhaust displacement pump P via valve V and condenser 9. In addition, pipe 3 for the condenser in which a cooling medium flows is twisted around the outer circumference of chamber 1.

In FIG. 2, cylindrical die material 10 engages the center hole of masking member 11, and molding transfer surface 10a at the upper portion is exposed. In this case, when die material 10 is placed on base 7, the side wall of die material 10 is not exposed to the mixed gas during thermal CVD, so that silicon carbide is not deposited there.

### EXAMPLE

### Example 1

Die material 10 was produced with silicon carbide by sintering, engaged masking member 11, and was placed on base 7 as shown in FIG. 1. Exhaust displacement pump P was operated so as to set the pressure inside chamber 1 to 100-300 torr. On the other hand, 3 moles of hydrogen gas as a carrier gas was mixed with 1 mole of silicon tetrachloride gas and 1 mole of methane gas, and the area around die material 10 was heated to 1200° C. employing carbon heater 6 to form a layer of silicon carbide. Further, after the film formation surface was subjected to a grinding treatment to obtain an aspheric surface, ductile mode cutting was conducted employing a diamond tool. Subsequently, a release film having a thickness of 1 μm was formed on a molding transfer surface. Obtained was an extremely excellent surface roughness for which concave portions were hardly generated on molding transfer surface 10a, resulting in a shape accuracy of the processed molding transfer surface of 48 nm.

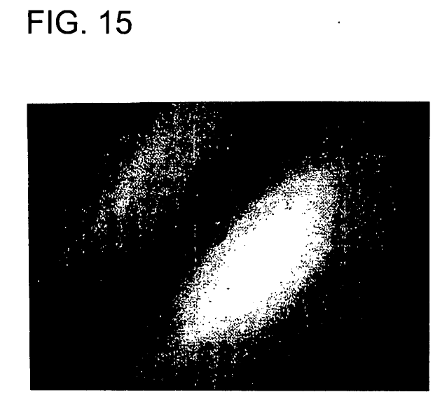

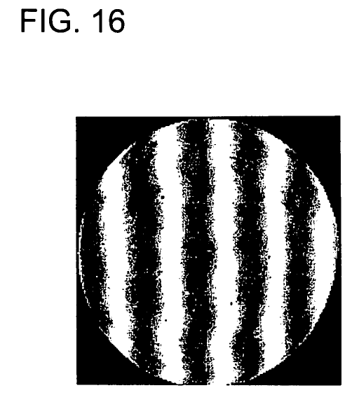

A glass lens was molded employing die 10, and an optical surface molding-transferred from molding transfer surface 10a is observed by a stereomicroscope. The results are shown in FIG. 15. The performance was also observed at the interference wavefront of a blue semiconductor laser. The results are shown in FIG. 16. As is clear from the figures, no scattering can be observed on the optical surface, and the interference wavefront having a wavefront aberration of 38 mλ is extremely excellent.

### Example 2

Under the similar conditions in Example 1, 5 moles of hydrogen gas as a carrier gas was mixed with 1 mole of silicon tetrachloride gas and 1 mole of methane gas to form a film on molding transfer surface 10a via the thermal CVD. An optical element was similarly molded employing die material 10, and an aspheric optical surface was molding-transferred from molding transfer surface 10a, but no generation of protrusions corresponding to concave portions was obtained, resulting in an excellent surface. Molding results of optical elements were also excellent, except that the film formation speed dropped from 100 μm/hr to 65 μm/hr.

### Example 3

Under the similar conditions in Example 1, 8 moles of hydrogen gas as a carrier gas was mixed with 1 mole of silicon tetrachloride gas and 1 mole of methane gas to form a film on molding transfer surface 10a via the thermal CVD. An optical element was similarly molded employing die material 10, and an aspheric optical surface was molding-transferred from molding transfer surface 10a, but no generation of protrusions corresponding to concave portions was obtained, resulting in an excellent surface. Molding results of optical elements were also excellent, except that the film formation speed dropped from 100 μm/hr to 20 μm/hr.

### EFFECT OF THE INVENTION

The present invention can provide a film formation method with which a layer having reduced defects, a die obtained by the film formation method, and a method of manufacturing the die.

What is claimed is:

1. A film formation method comprising the step of:
forming a film of a carbide via a thermal CVD employing a hydrogen, and a chloride or a hydrocarbon used as a raw material gas,
wherein a gas flow rate of the hydrogen is 3-8 times larger than a gas flow rate of the chloride or the hydrocarbon.

2. The film formation method of claim 1,
wherein the carbide is silicon carbide.

3. A die formed by the film formation method of claim 1, wherein when cutting a surface of a substrate on which the film of the carbide is formed to form a molding transfer surface, the number of cutting chips per unit area of the cut surface is at most 1000/mm².

4. A method of manufacturing a die, comprising the steps of:
(a) forming a film of a carbide on a surface of a substrate via a thermal CVD, with controlling that a hydrogen gas flow rate is 3-8 times larger than a gas flow rate of a chloride or a hydrocarbon used as a raw material gas; and
(b) forming a molding transfer surface by ductile-mode-cutting the surface of the substrate on which the film of the carbide is formed employing a diamond tool.

5. The method of Claim 4, further comprising the step of: molding-transferring from the molding transfer surface to an optical surface of an optical element,
wherein the die is employed to mold the optical element.

6. The method of Claim 4,
wherein the carbide is silicon carbide.

7. The method of Claim 4, further comprising the step of:
forming a release film on the molding transfer surface.
